(19) United States
(12) Patent Application Publication
(10) Pub. No.: US 2005/0276350 A1
(43) Pub. Date: Dec. 15, 2005

(54) Signal processing architecture for modulation and interpolation

(76) Inventor: Yunchu Li, Andover, MA (US)

Correspondence Address: John L. Conway;Bromberg & Sunstein LLP, 125 Summer Street, Boston, MA, 02110-1618, US

(21) Appl. No.: 10/866,893

(22) Filed: Jun. 14, 2004

(51) Int. Cl. H03C 3/00; H03K 7/06; H04L 27/12; G06F 17/17

(52) U.S. Cl. 375/302; 708/313

(57) ABSTRACT

A system and method for oversampling and modulating a digital data stream. A programmable quadrature interpolating filter is provided which allows the passband of the output signal to be selected from a set of mode selections. The set of mode selections provide overlapping passbands spanning the Nyquist range of the filter. The filter allows a signal to be shifted to a desired carrier frequency before the signal is oversampled and filtered, reducing power consumption in devices such as digital-to-analog converters.

### TECHNICAL FIELD

The present invention relates to methods and devices for converting electrical signals from digital to analog format.

### BACKGROUND

Interpolation and complex modulation are two important functions frequently provided by a signal processing digital-to-analog converter (“DAC”). Interpolation is the process of creating “in-between” samples of a digital signal that are interleaved with the original digital samples (oversampling) and then filtering the output. Filtering removes frequency artifacts from the signal that are introduced by the oversampling. Interpolation increases the sampling rate of the input signal to match the sampling rate of a subsequent signal processing stage. Modulation shifts the center frequency of the digital signal to a desired carrier frequency.

FIG. 1 shows a traditional architecture 100 for implementing these functions. First, interpolation is performed on the components of a complex input data stream 110 by separate real interpolation filters 120, 130, and then a complex multiplier (modulator) 140 shifts the digital data stream to a desired output frequency. Analog signals for each stream are then generated 160, 170 by a DAC stage. A disadvantage of the traditional approach is the need, in general, for a high speed digital local oscillator 150 and modulator 140 to shift the transmission signal frequency to the desired output frequency in the DAC's Nyquist range. As DAC clock speeds exceed 1 giga-samples-per-second (“GSPS”), the digital oscillator and modulator design becomes increasingly complex and increasing power consumption becomes a concern.

### SUMMARY OF THE INVENTION

In an embodiment of the invention, a system is provided for modulating and interpolating a digital data stream. The system includes an input for receiving the digital data stream and a complex modulator for shifting the frequency of the stream to a desired carrier frequency. An interpolator oversamples the frequency shifted stream increasing the clock rate of the system to a desired clock rate. A filter removes undesirable frequency artifacts introduced by the oversampling. In some embodiments of the invention the output of the filter is coupled to a digital-to-analog converter to convert the digital data stream from the filter to an analog output.

In another embodiment of the invention, a programmable interpolating filter is provided. The filter receives, oversamples and filters a digital data stream. The interpolation rate and the passband of the filter are determined by a mode selection input to the filter. In specific embodiments of the invention, the filter may be configured so that the filter has at least one mode that passes a digital data stream with any center frequency within a range of center frequencies if the bandwidth of the stream is less than a given bandwidth. In an embodiment of the invention, the range of center frequencies corresponds to the Nyquist range of the filter.

In other embodiments of the invention, programmable interpolating filters may be coupled in series to provide desired interpolation rates and output frequencies. In some embodiments of the invention, a programmable filter may be coupled to a real input data stream to produce a complex output stream. This complex output data stream may then be modulated by a complex modulator and output to one or more programmable interpolating filters to produce a desired output.

### BRIEF DESCRIPTION OF THE DRAWINGS

The foregoing features of the invention will be more readily understood by reference to the following detailed description, taken with reference to the accompanying drawings, in which:

FIG. 1 is a block diagram of a prior art digital-to-analog converter architecture;

FIG. 3A is a diagram of a prior art filter for use in the digital-to-analog converter of FIG. 1;

FIG. 2B shows the frequency response of the filter of FIG. 2A;

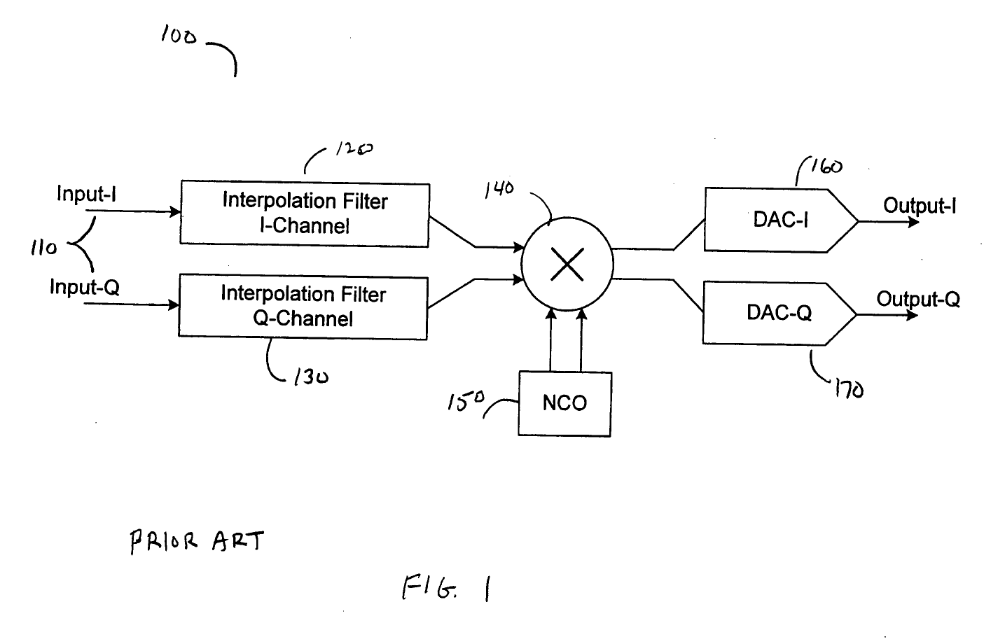

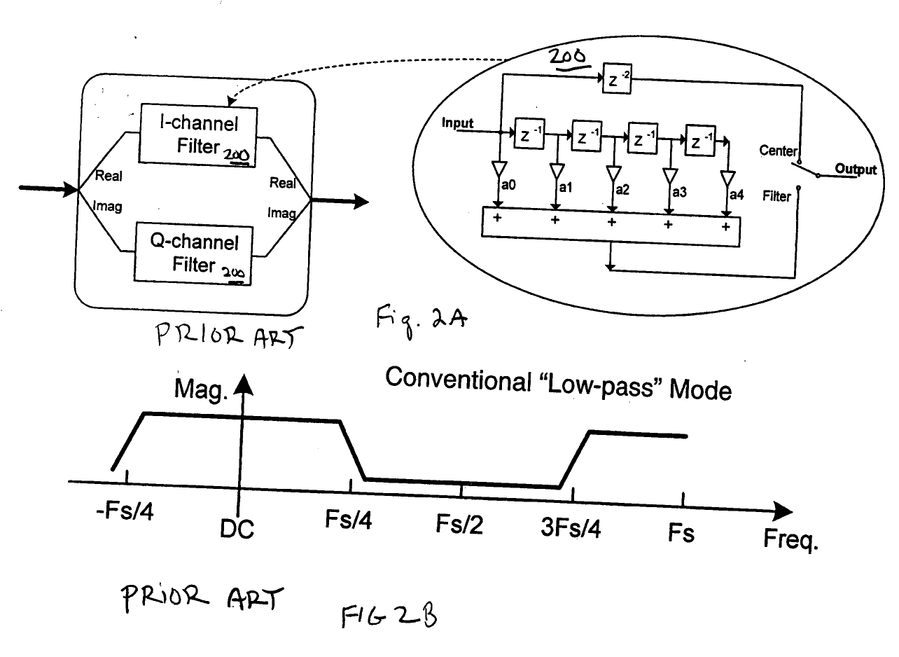

FIG. 2A is a diagram of another prior art filter for use in the digital-to-analog converter of FIG. 1;

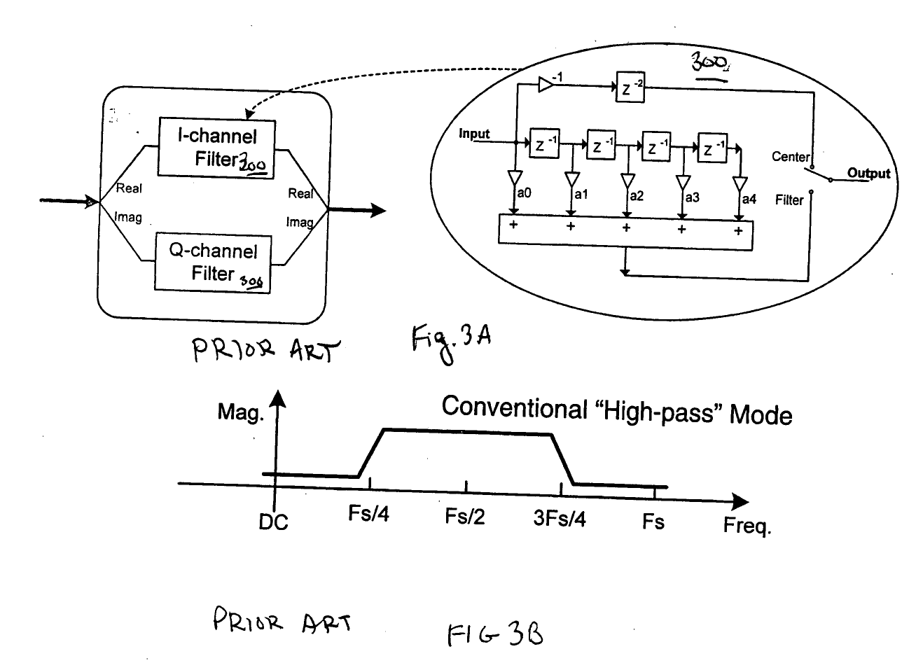

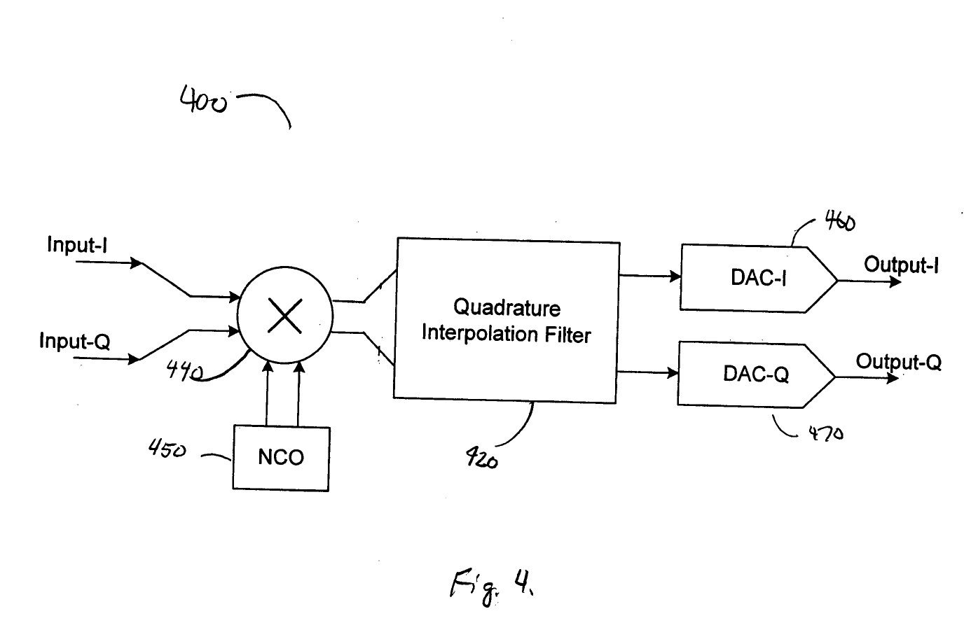

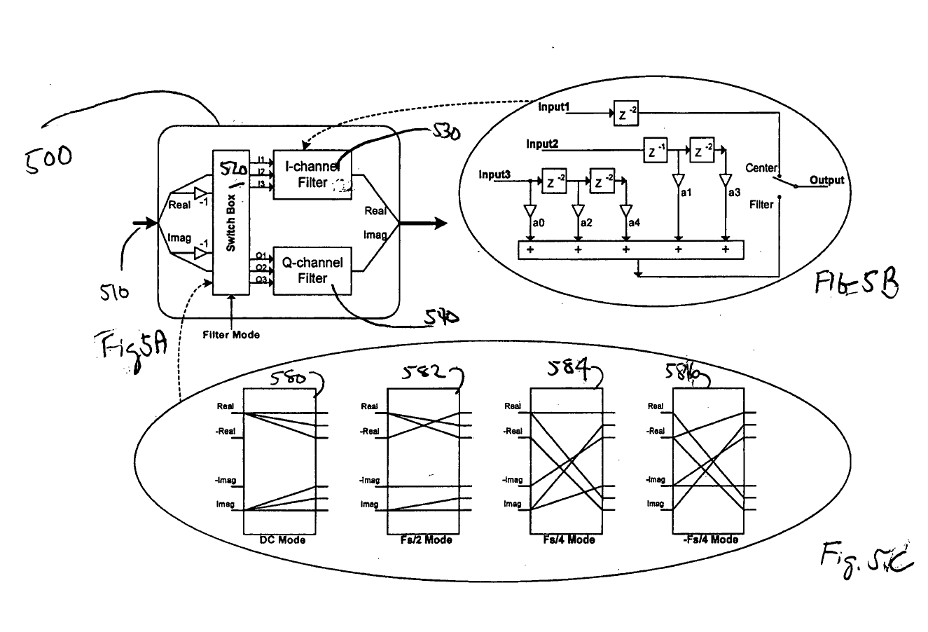

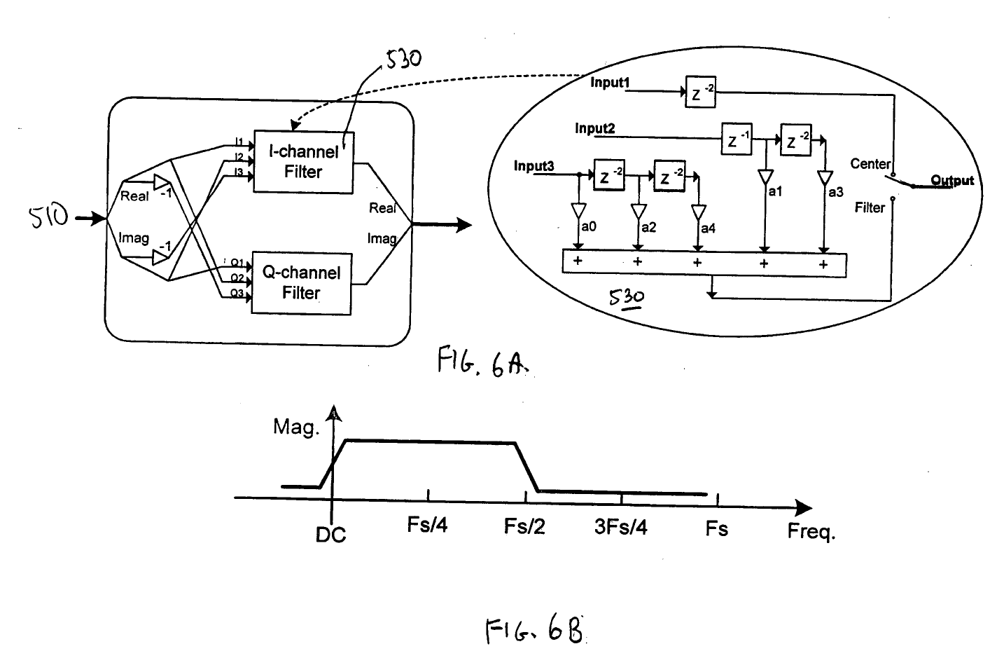

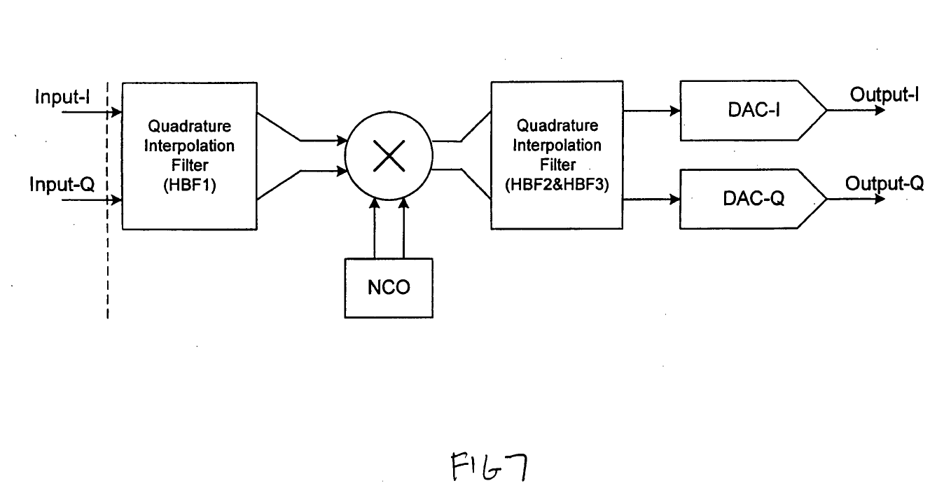

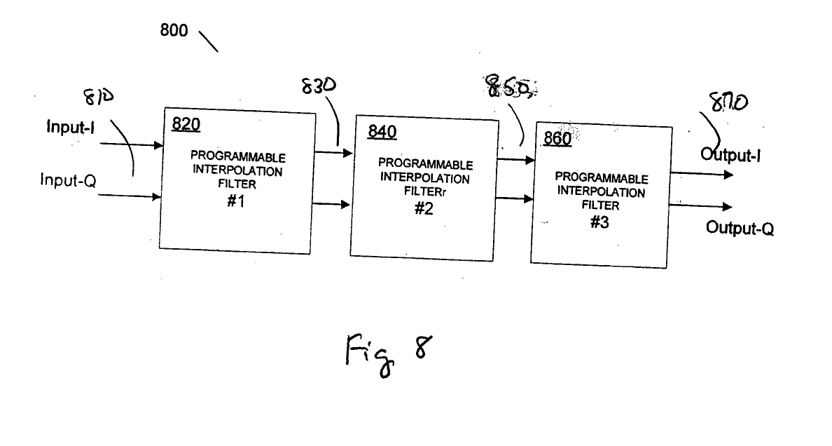

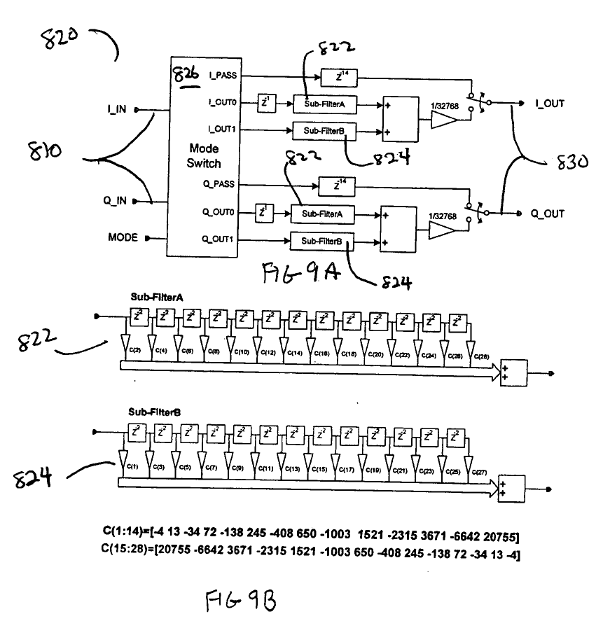

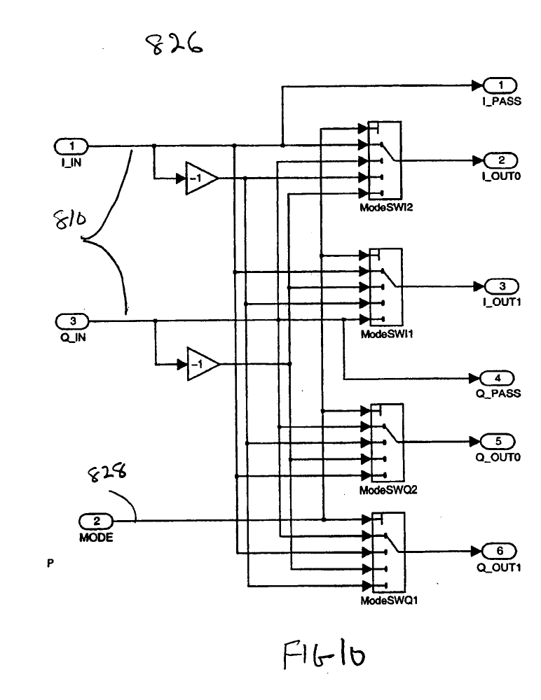

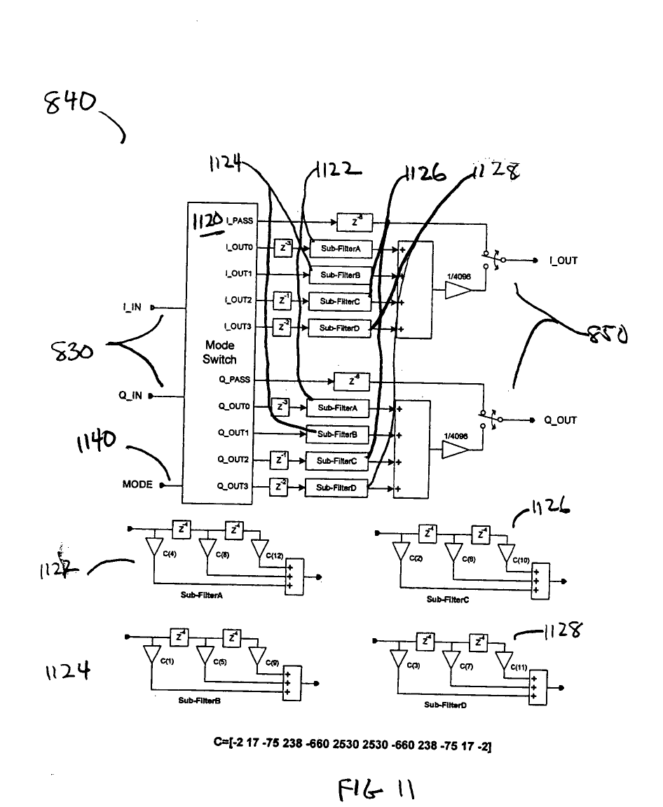

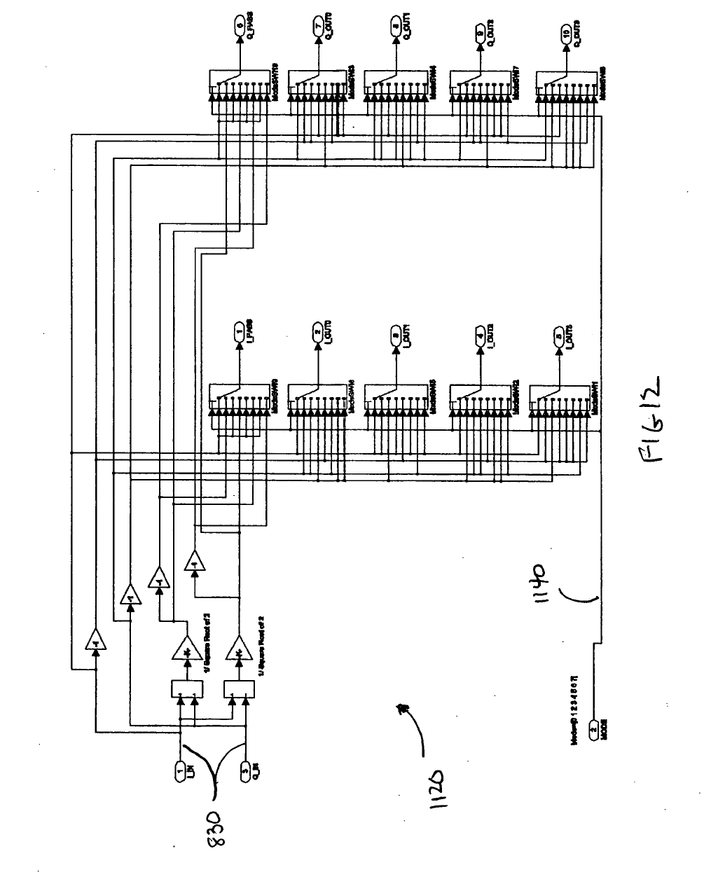

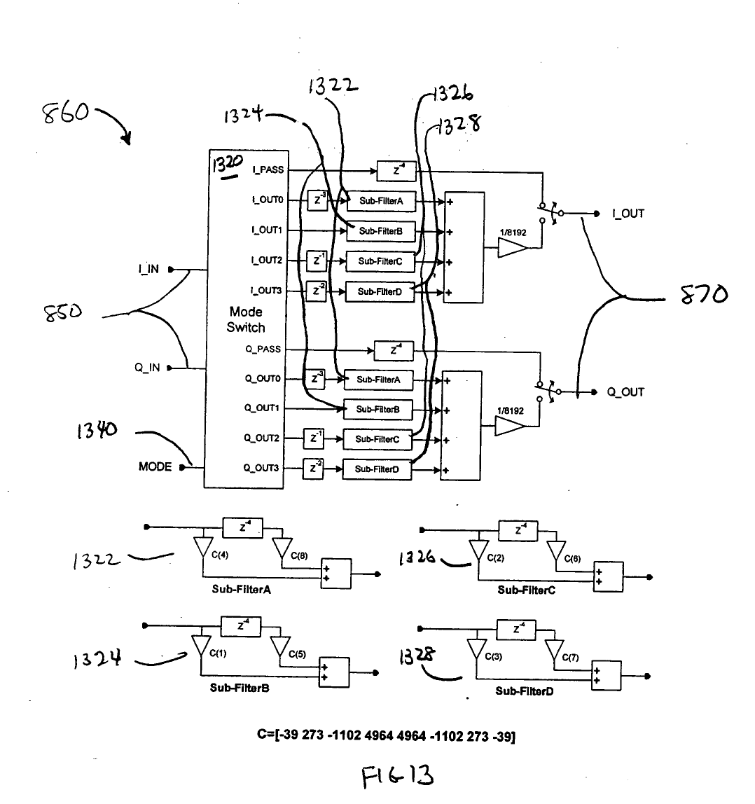

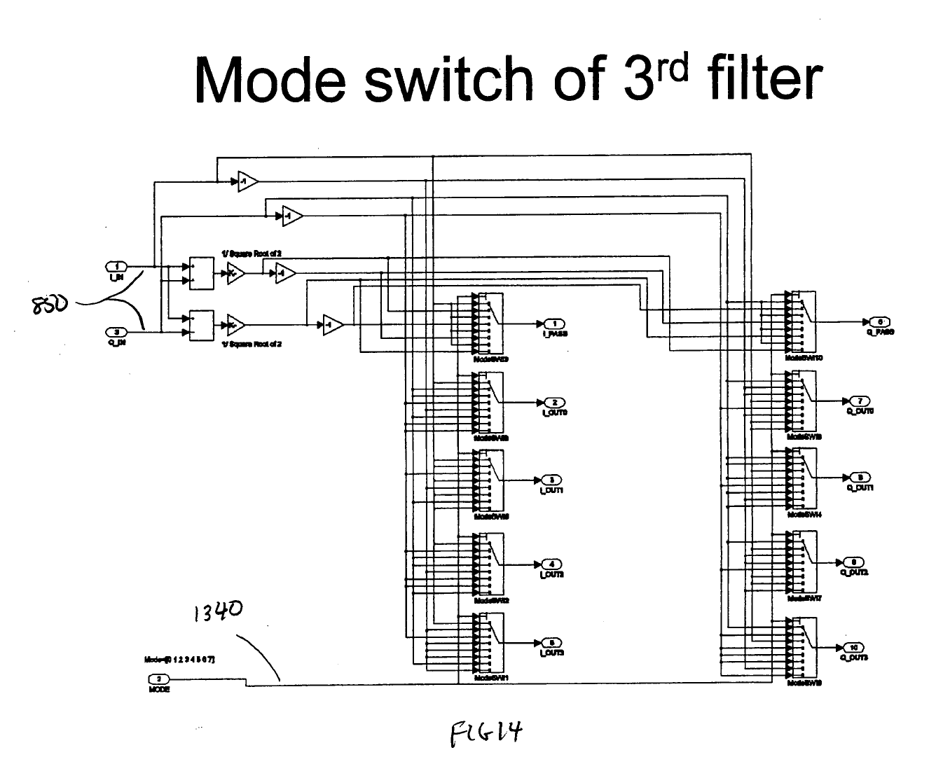

FIG. 3B shows the frequency response of the filter of FIG. 3A;

FIG. 4 is a block diagram of a digital-to-analog converter architecture according to an embodiment of the present invention;

FIGS. 5A-C are block diagrams showing a programmable quadrature interpolation filter according to an embodiment of the invention;

FIG. 6A is a diagram of one of the modes of the programmable filter of FIGS. 5A-C;

FIG. 6B shows the frequency response of the filter of FIG. 6A;

FIG. 7 is a block diagram of a digital-to-analog converter architecture according to another embodiment of the present invention;

FIG. 8 is a block diagram of a series of programmable interpolating filters according to another embodiment of the present invention;

FIG. 9A is a block diagram the first programmable interpolating filter for the embodiment shown in FIG. 8;

FIG. 9B shows the sub-filter design for the filter shown in FIG. 9A;

FIG. 10 is a diagram for the mode switch for the filter shown in FIG. 9A;

FIG. 11 is a block diagram for the second programmable interpolating filter for the embodiment shown in FIG. 8;

FIG. 12 is a diagram for the mode switch for the filter shown in FIG. 11;

FIG. 13 is a block diagram for the third programmable interpolating filter for the embodiment shown in FIG. 8; and

FIG. 14 is a diagram for the mode switch for the filter shown in FIG. 13.

### DETAILED DESCRIPTION OF SPECIFIC EMBODIMENTS

In illustrative embodiments of the invention, a system is provided for modulating and interpolating a digital signal for digital-to-analog conversion. First a complex digital data stream is received and then modulated to shift the center frequency of the signal to a desired intermediate frequency. The frequency shifted complex data stream is then input to an interpolation filter. The interpolation filter oversamples the signal and may further frequency shift the complex data stream to a desired output frequency. The interpolation filter may be programmable allowing the desired output frequency to be selected from any frequency within the Nyquist range of the filter. This system organization allows complex modulation to be performed prior to oversampling. Compared to conventional organizations where modulation is performed after oversampling, the lower sampling rate at which the complex modulation is performed saves power and simplifies the design.

In certain embodiments of the present invention, a programmable quadrature interpolation filter is provided for use, for example, in digital-to-analog converters. In this filter, a complex digital data stream is received by a programmable multiplexer. The multiplexer generates output signals for each of two filters. The specific output signal(s) passed to each filter are determined by the mode selected for the multiplexer. Each filter interpolates (oversamples) the received data stream and generates an output signal in a given passband, corresponding to the selected mode. The passbands corresponding to the modes of the multiplexer overlap substantially. The filter may be designed so that the passbands span the Nyquist range of the filter. Thus, it is possible to interpolate (oversample) an input data stream and selectively pass the oversampled stream through the filter at any given frequency in the Nyquist range for the filter, such that the output of the filter is representative of the input data stream.

FIG. 2A shows a prior art interpolating filter, labeled generally 200, that can be used in the organization of FIG. 1. FIG. 2B shows the frequency response of the filter 200. The filter is a low pass filter, allowing a baseband image of the input signal to pass with an approximate high frequency cutoff of Fs/4, where Fs is the output data rate of the filter. Likewise, FIG. 3A shows a corresponding “high pass” interpolating filter 300. FIG. 3B shows the frequency response of the filter 300. Note that these filters typically only pass signals up to about 80% of the Nyquist bandwidth of the filter and within this band certain dead zones exist, e.g., Fs/4. (The Nyquist bandwidth or range of a real filter or other digital signal processing device extends from DC to a frequency that is one half of the clock (sampling) rate. For example, the Nyquist range of a filter that is clocked at 1 giga-samples-per-second is from DC to 500 MHz. For a quadrature filter this range is doubled to also include frequencies from negative one half of the clock rate to DC.)

FIG. 4 shows an organization for a DAC 400 that divides the modulation process into multiple steps (distributed modulation), according to an embodiment of the invention. This organization capitalizes on the fact that the interpolation process itself is a modulation process. Interpolation generates multiple images of the input signal at higher frequencies, as the Nyquist range is expanded. The Nyquist range for the filter is expanded as the sampling rate is increased. In conventional DAC architectures, these higher frequency images are typically filtered out by the interpolation filters, leaving the baseband signal. The interpolation filter 420 may be a programmable filter, where the center frequency of the filter is determined by a mode selection and the bandwidth of the passband is the same for each mode. The filter may be implemented so that the set of passband modes for the filter covers the Nyquist range of the filter. Consequently, the digital local oscillator 450 and multiplier 440 (modulator) can be placed before the interpolation filter. The input signal may thereby be frequency shifted to a carrier frequency anywhere within the Nyquist range of the filter, corresponding to the selected mode for the filter. Shifting the input signal to the output carrier frequency can thus be accomplished at a lower clock sampling rate. If placed before the interpolation filters, the clock rate of the digital local oscillator and multiplier can be 1/N times the DAC clock rate, where N is the interpolation factor of the filter 420. This reduction in the clock rate of the digital local oscillator and multiplier from the DAC clock rate to 1/N times the DAC clock rate can mean a significant reduction in power consumption and circuit complexity for the DAC. In certain embodiments of the invention, the programmable interpolating filter may consist of a plurality of filters connected sequentially. This arrangement allows for considerable flexibility in selecting the overall interpolation factor of the string of filters and the set of passbands corresponding to the modes of the filters.

FIG. 5A shows a programmable interpolation filter 500 according to an embodiment of the invention. This filter may be used in the architecture shown in FIG. 4. The filter 500 receives a complex digital data stream 510, comprising in-phase and quadrature stream components. The filter includes a programmable multiplexer 520 and two digital filters 530, 540, one for the in-phase channel and one for the quadrature channel. FIG. 5B shows the details of the digital interpolating filter used in each channel. Each filter has three inputs (inputs 1, 2, and 3) for receiving digital signals. The coefficients of the filter (a0, a1, a2, a3, a4) are chosen to provide a desired passband, as known to those skilled in the art. The programmable multiplexer 520 selectively routes the in-phase and quadrature data stream components and their inverses to inputs 1, 2, and 3 of each of the filters. The signal routing by the multiplexer depends on the filter mode selected. FIG. 5c shows the details of the signal routing to the filter inputs for each of the four filter modes 580, 582, 584, 586. The center frequencies of the passbands for these modes are DC, Fs/2, Fs/4 and 3Fs/4 respectively, where Fs is the output data rate of the filter and Fs/2 is the sampling rate of the input data stream 510. The interpolation factor of the filter is 2×.

FIG. 6A shows the signal routing for the third filter mode 584 (the Fs/4 mode) of FIG. 5C. FIG. 6B shows the passband of the output of the filter for this mode. The center frequency of the passband for this mode is Fs/4 with a bandwidth extending approximately from DC to Fs/2, where Fs is the output sampling rate. The passbands for the other three modes have the same bandwidth and are centered at DC, Fs/2 and 3Fs/4 respectively. Note that each passband overlaps substantially with an adjacent passband. In the case of Fs/4 and Fs/2, each of these passbands overlaps substantially with two adjacent passbands. Thus, by selecting the proper mode, the interpolating filter can pass a data stream with a center frequency at any frequency within the Nyquist range of the filter.

Any number of reconfigurable interpolation filters may be connected in series to generate a desired interpolation factor corresponding to a desired level of oversampling. The passbands of the filters are selected to pass the carrier frequency of the output signal. In certain embodiments of the invention, interpolating filters may be placed both before and after the modulator and local oscillator that generates the carrier frequency. For example, in the organization of FIG. 7, a complex filter is placed before the local oscillator. Additional reconfigurable interpolating filters are placed after the local oscillator. The first filter, which does not perform interpolation, may be used, for example, to generate a quadrature output signal for use with the complex modulator, if only a real input signal is available. The local oscillator signal modulates the output of the first filter to produce a signal representative of the input signal at a carrier frequency.

FIG. 8 shows a block diagram for a programmable interpolating filter system 800 according to another embodiment of the present invention. Three 2× programmable interpolating filters 820, 840, 860 are arranged sequentially. A complex input signal 810 is input to the first stage filter 820. The output 830 of the first stage is input to the second stage and the output of the second stage 850 is input to the third stage. Depending on the mode selected for each filter, the three programmable filters may be used to interpolate the input signal by a factor of 8×. If filter 3 is bypassed, an interpolation factor of 4× can be obtained, while if both filters 2 and 3 are bypassed, an interpolation factor of 2× can be obtained.

Table 1 shows the characteristics of the combined modes of the three filters. (Note that the characteristics presented for this embodiment of the invention have been derived from simulation of the hardware rather than measurement). In certain modes of the filter system, filter 2 or filters 2 and 3 may be bypassed. Note also that the column labeled “modulation” shows the frequency offset that is added to the input frequency by the filter system. If the desired carrier frequency of the output signal from the filter system matches one of the modulation frequencies, then a separate input or output modulator may be eliminated from the overall system architecture. For example, if the filter system is used in a DAC and the input signal is at baseband, then if the output carrier frequency matches one of the modulation frequencies of the filter system, the complex modulator that may be provided with the DAC may be “powered down”, saving power. Further, if only a real or only an imaginary output signal is needed from the filter system, one channel of the last filter may be shut down to conserve power.

TABLE 1
Filter Modes

| In- | Filter | | | Filter | Mod- | | | |
|---|---|---|---|---|---|---|---|---|
| terpolation | 1 | Filter 2 | | 3 | ula- | | | |
| Factor | mode | mode | | mode | tion | F low* | F center | F high |
| 8 | 0 | | 0 | 0 | DC | −0.05 | 0 | 0.05 |
| 8 | 1 | | 1 | 0 | DC | 0.0125 | 0.0625 | 0.1125 |
| 8 | 2 | | 2 | 1 | F/8 | 0.075 | 0.125 | 0.175 |
| 8 | 3 | | 3 | 2 | F/8 | 0.1375 | 0.1875 | 0.2375 |
| 8 | 0 | | 4 | 2 | 2F/8 | 0.2 | 0.25 | 0.3 |
| 8 | 1 | | 5 | 2 | 2F/8 | 0.2625 | 0.3125 | 0.3625 |
| 8 | 2 | | 6 | 3 | 3F/8 | 0.325 | 0.375 | 0.425 |
| 8 | 3 | | 7 | 4 | 3F/8 | 0.3875 | 0.4375 | 0.4875 |
| 8 | 0 | | 0 | 4 | 4F/8 | 0.45 | 0.5 | 0.55 |
| 8 | 1 | | 1 | 4 | 4F/8 | 0.5125 | 0.5625 | 0.6125 |
| 8 | 2 | | 2 | 5 | 5F/8 | 0.575 | 0.625 | 0.675 |
| 8 | 3 | | 3 | 6 | 5F/8 | 0.6375 | 0.6875 | 0.7375 |
| 8 | 0 | | 4 | 6 | 6F/8 | 0.7 | 0.75 | 0.8 |
| 8 | 1 | | 5 | 6 | 6F/8 | 0.7625 | 0.8125 | 0.8625 |
| 8 | 2 | | 6 | 7 | 7F/8 | 0.825 | 0.875 | 0.925 |
| 8 | 3 | | 7 | 0 | 7F/8 | 0.8875 | 0.9375 | 0.9875 |
| 4 | 0 | | 0 | OFF | DC | −0.1 | 0 | 0.1 |
| 4 | 1 | | 1 | OFF | DC | 0.025 | 0.125 | 0.225 |
| 4 | 2 | | 2 | OFF | F/4 | 0.15 | 0.25 | 0.35 |
| 4 | 3 | | 3 | OFF | F/4 | 0.275 | 0.375 | 0.475 |
| 4 | 0 | | 4 | OFF | F/2 | 0.4 | 0.5 | 0.6 |
| 4 | 1 | | 5 | OFF | F/2 | 0.525 | 0.625 | 0.725 |
| 4 | 2 | | 6 | OFF | 3F/4 | 0.65 | 0.75 | 0.85 |
| 4 | 3 | | 7 | OFF | 3F/4 | 0.775 | 0.875 | 0.975 |
| 2 | 0 | OFF | | OFF | DC | −0.2 | 0 | 0.2 |
| 2 | 1 | OFF | | OFF | DC | 0.05 | 0.25 | 0.45 |
| 2 | 2 | OFF | | OFF | F/2 | 0.3 | 0.5 | 0.7 |
| 2 | 3 | OFF | | OFF | F/2 | 0.55 | 0.75 | 0.95 |

*Note that the frequencies shown in table 1 are normalized to F_{DAC} The filter bandwidth is assumed to be 80% of the input data rate.

FIG. 9A is a block diagram of the first stage filter 820 for the embodiment of FIG. 8. The first stage filter receives complex data stream 810 and outputs complex data stream 830 for the second stage filter 840. FIG. 9B shows the design of filter A 822 and filter B 824. Note that Z⁻¹ is a one period delay of the input data clock. The first stage filter 820 has four selectable modes, which are shown in Table 1:
Mode 0—center frequency is at DC;
Mode 1—center frequency is at Fs/4;
Mode 2—center frequency is at Fs/2; and
Mode3—center frequency is at 3Fs/4 (−Fs/4).

FIG. 10 shows a mode switch 826 (multiplexer) for the first stage filter. The mode switch receives real and quadrature input signals 810, generates inverted versions of each signal, and then routes these signals based on the mode selection 828 to filtering elements 822, 824. The signals passed to the filtering elements for a given mode determine the center frequency of the passband for the first stage filter 820. The mode switch position shown is for mode 0, which can pass a baseband signal, for example.

FIG. 11 is a block diagram for the second stage filter 840, while FIG. 13 is a similar diagram for the third stage filter 860 for the embodiment of FIG. 8. Each filter stage receives a complex digital data stream 830 (850 for the third stage filter) and produces a complex output digital data stream 850 (870 for the third stage filter). The second and third stage filters have eight different modes, as shown in Table 1:
Mode 0 center frequency is at DC;
Mode 1 center frequency is at Fs/8;
Mode 2 center frequency is at Fs/4;
Mode 3 center frequency is at 3Fs/8;
Mode 4 center frequency is at Fs/2;
Mode 5 center frequency is at 5Fs/8 (−3Fs/8);
Mode 6 center frequency is at 3Fs/4 (−Fs/4); and
Mode 7 center frequency is at 7Fs/8 (−Fs/8).

FIG. 12 shows the mode switch 1120 for the second stage filter while FIG. 14 shows the mode switch for the third stage filter. Mode switch 1120 performs a function similar to the function of mode switch 826 in the first stage filter, routing the input signals 830 to the filtering elements 1122-1128. The mode of the filter is selected by a mode input signal 1140. The mode switch position shown is for mode 0. Similar details are shown in FIG. 14 for the third stage filter.

As will be appreciated by those skilled in the art, various designs for the programmable filters may be employed in embodiments of the invention, depending on the degree of interpolation desired, and the passband characteristics desired. All such designs are intended to be within the scope of the invention as described in the appended claims.

The present invention may be embodied in many different forms, including, but in no way limited to, computer program logic for use with a processor (e.g., a microprocessor, microcontroller, digital signal processor, or general purpose computer), programmable logic for use with a programmable logic device (e.g., a Field Programmable Gate Array (FPGA) or other PLD), discrete components, integrated circuitry (e.g., an Application Specific Integrated Circuit (ASIC)), or any other means including any combination thereof.

Computer program logic implementing all or part of the functionality previously described herein may be embodied in various forms, including, but in no way limited to, a source code form, a computer executable form, and various intermediate forms (e.g., forms generated by an assembler, compiler, linker, or locator.) Source code may include a series of computer program instructions implemented in any of various programming languages (e.g., an object code, an assembly language, or a high-level language such as Fortran, C, C++, JAVA, or HTML) for use with various operating systems or operating environments. The source code may define and use various data structures and communication messages. The source code may be in a computer executable form (e.g., via an interpreter), or the source code may be converted (e.g., via a translator, assembler, or compiler) into a computer executable form.

The computer program may be fixed in any form (e.g., source code form, computer executable form, or an intermediate form) either permanently or transitorily in a tangible storage medium, such as a semiconductor memory device (e.g., a RAM, ROM, PROM, EEPROM, or Flash-Programmable RAM), a magnetic memory device (e.g., a diskette or fixed disk), an optical memory device (e.g., a CD-ROM), a PC card (e.g., PCMCIA card), or other memory device. The computer program may be fixed in any form in a signal that is transmittable to a computer using any of various communication technologies, including, but in no way limited to, analog technologies, digital technologies, optical technologies, wireless technologies, networking technologies, and internetworking technologies. The computer program may be distributed in any form as a removable storage medium with accompanying printed or electronic documentation (e.g., shrink wrapped software or a magnetic tape), preloaded with a computer system (e.g., on system ROM or fixed disk), or distributed from a server or electronic bulletin board over the communication system (e.g., the Internet or World Wide Web.)

Hardware logic (including programmable logic for use with a programmable logic device) implementing all or part of the functionality previously described herein may be designed using traditional manual methods, or may be designed, captured, simulated, or documented electronically using various tools, such as Computer Aided Design (CAD), a hardware description language (e.g., VHDL or AHDL), or a PLD programming language (e.g., PALASM, ABEL, or CUPL.)

Other embodiments of the invention may employ programmable interpolating filters with different numbers of stages, center frequencies and passbands as may readily be designed by those skilled in the art. Other variations and modifications of the embodiments described above are intended to be within the scope of the present invention as defined in the appended claims.

1. A system for processing a digital signal comprising:
a. an input for receiving the digital signal;
b. a modulator operatively coupled to the input, the modulator configured to produce a frequency-shifted digital signal;
c. An interpolator operatively coupled to the modulator, the interpolator configured to produce an oversampled digital signal from the frequency-shifted signal; and
d. A filter operatively coupled to the interpolator, the filter configured to produce a filtered digital signal;

2. The system of claim 1 further including:
e. a converter operatively coupled to the filter, the converter configured to produce an analog output signal from the filtered digital signal.

3. The system of claim 1 wherein the modulator is a complex modulator.

4. The system of claim 1 wherein the filter is a programmable filter, the filter including a plurality of modes.

5. The system of claim 4 wherein the modes of the filter correspond to passbands spanning the Nyquist range of the filter.

6. The system of claim 1 further including a quadrature input filter configured to receive a real digital signal and to output the digital signal, wherein the digital signal is a complex signal.

7. A programmable interpolation filter for interpolating and filtering a complex digital data input stream, the frequency spectrum of the stream characterized by a center frequency and a bandwidth, the filter comprising:
a. a programmable multiplexer configured to receive the input stream and output a plurality of signals representing the input stream, the multiplexer output signals corresponding to a given multiplexer mode chosen from a plurality of modes;
b. a first interpolation filter; the first filter configured to receive and interpolate at least one signal from the multiplexer and produce an in-phase output signal; and
c. a second interpolation filter; the second filter configured to receive and interpolate at least one signal from the multiplexer and produce a quadrature output signal,
wherein the plurality of multiplexer modes are configured so that at least one mode allows the filter to pass the input stream with the frequency spectrum of the stream substantially unchanged when the stream center frequency is anywhere within a range of frequencies and the bandwidth is less than a given bandwidth.

8. A filter according to claim 7 wherein the range of frequencies equals the Nyquist range for the filter.

9. A filter system according to claim 7 further including a second programmable interpolation filter operatively coupled to the programmable interpolation filter.

10. A filter system according to claim 8 wherein at least one of the two filters may be bypassed.

11. A filter system according to claim 7, further including:
a complex modulator, the modulator receiving an input complex data stream at a first frequency and outputting the complex digital data stream to the multiplexer at a second carrier frequency.

12. A filter system according to claim 10, wherein the data stream is a real data stream.

13. A method for processing a digital input data stream the method comprising:
a. receiving the digital input data stream;
b. modulating the digital input data stream and producing a frequency-shifted data stream; and
c. interpolating and filtering the frequency-shifted data stream to produce an oversampled frequency-shifted data stream representative of the digital input data stream.

14. A method according to claim 13 further including:
converting the oversampled frequency-shifted data stream to an analog output stream.

15. A method according to claim 13 wherein the digital input data stream is a complex data stream.

16. A method according to claim 13 wherein modulating the digital input data stream includes complex modulation.

17. A method according to claim 13 wherein interpolating and filtering the frequency-shifted data stream includes selecting a mode of a programmable interpolation filter.

18. A method according to claim 17 wherein the programmable interpolation filter includes a plurality of modes wherein the plurality of multiplexer modes are configured so that at least one mode allows the filter to pass the digital input data stream with the frequency spectrum of the stream substantially unchanged when the stream center frequency is anywhere within a range of frequencies and the stream bandwidth is less than a given bandwidth.

19. A method according to claim 18 wherein the range of frequencies equals the Nyquist range for the filter.
